(19) United States
(12) Patent Application Publication
(10) Pub. No.: US 2019/0212647 A1
(43) Pub. Date: Jul. 11, 2019

(54) COMPOSITION FOR FORMING PRIMER LAYER FOR IMPRINTING, PRIMER LAYER FOR IMPRINTING, AND LAMINATE

(71) Applicant: FUJIFILM Corporation, Tokyo (JP)

(72) Inventor: Yuichiro GOTO, Yoshida-cho (JP)

(73) Assignee: FUJIFILM Corporation, Tokyo (JP)

(21) Appl. No.: 16/353,432

(22) Filed: Mar. 14, 2019

Related U.S. Application Data
(63) Continuation of application No. PCT/JP2017/032757, filed on Sep. 12, 2017.

(30) Foreign Application Priority Data
Sep. 16, 2016 (JP) 2016-182386

(51) Int. Cl. G03F 7/00; C08G 65/08; C08L 35/02; C08L 71/02; C09D 171/02; C09D 135/02

(52) U.S. Cl. CPC G03F 7/0002; C08G 65/08; C08L 35/02; H01L 21/0271; C09D 171/02; C09D 135/02; C08L 2203/20; C08L 71/02

(57) ABSTRACT

An object of the present invention is to improve wettability of a curable composition for imprinting on a substrate. There is provided a novel composition for forming a primer layer for imprinting, a primer layer in which the above-described composition for forming a primer layer is used, and a laminate. Provided is a composition for forming a primer layer for imprinting which satisfies at least one of A and B.
A: A component having a surface tension of greater than or equal to 40 mN/m at 25° C. is contained.
B: A critical surface tension of a primer layer formed of the composition for forming a primer layer for imprinting is greater than or equal to 46 mN/m at 25° C.

### CROSS-REFERENCE TO RELATED APPLICATIONS

This application is a Continuation of PCT International Application No. PCT/JP2017/032757 filed on Sep. 12, 2017, which claims priority under 35 U.S.C § 119(a) to Japanese Patent Application No. 2016-182386 filed on Sep. 16, 2016. Each of the above application(s) is hereby expressly incorporated by reference, in its entirety, into the present application.

### BACKGROUND OF THE INVENTION

### 1. Field of the Invention

The present invention relates to a composition for forming a primer layer for imprinting, a primer layer for imprinting, and a laminate.

### 2. Description of the Related Art

An imprinting method is a method for radiating light through a light-transmitting mold or a light-transmitting substrate, and photohardening a curable composition for imprinting, followed by peeling the mold to transfer a fine pattern to a hardened product. Since this method enables imprinting at room temperature, it can be applied to a precision processing field of ultrafine patterns such as production of a semiconductor integrated circuit. In recent years, new developments such as a nanocasting method in which advantages of both methods are combined or a reversal imprinting method in which a three-dimensional lamination structure is produced have been reported.

Here, adhesiveness between a substrate and a curable composition for imprinting accompanied by activation of the imprinting method has become a problem. That is, in the imprinting method, a surface of the substrate is coated with the curable composition for imprinting which is then irradiated with light in a state in which the surface thereof is brought into contact with the mold and hardened, and the mold is peeled off. However, in the step of peeling off the mold, the hardened product may be peeled off from the substrate and attached to the mold in some cases. It is considered that this is because adhesiveness between the substrate and the hardened product is lower than that between the mold and the hardened product. It has been studied that an adhesive layer for imprinting which improves the adhesiveness between the substrate and the hardened product is used (JP2009-503139A, JP2014-024322A, and JP2014-192178A) in order to solve such a problem.

### SUMMARY OF THE INVENTION

However, it has been found that, in a case where a curable composition for imprinting is applied onto a surface of an adhesive layer in the related art, filling properties of the curable composition for imprinting may deteriorate in some cases. In particular, in a case where the curable composition for imprinting is applied through an inkjet (IJ) method, liquid droplets of a curable composition for imprinting 22 are added dropwise onto a surface of an adhesive layer 21 at equal intervals as shown in FIG. 2, for example, the above-described liquid droplets spread on the adhesive layer 21 to form a layer-shaped curable composition for imprinting 22. However, in a case where wettability of the curable composition for imprinting is low, in some cases, the curable composition for imprinting may not spread on the adhesive layer 21 and a portion where the adhesive layer 21 is not filled with the curable composition for imprinting 22 may remain. That is, it is necessary to improve the wettability of the curable composition for imprinting on the adhesive layer 21.

An object of the present invention is to improve the wettability of the curable composition for imprinting on the substrate to solve the problem. Specifically, the object of the present invention is to provide a novel composition for forming a primer layer for imprinting, a primer layer for imprinting, and a laminate for solving the above-described problem.

On the basis of the above-described problem, it was found that the above-described problem can be solved using a primer layer as an underlayer to be coated with a curable composition for imprinting.

Specifically, the above-described problem has been solved by means <1> and preferably means <2> to <15>.

<1> A composition for forming a primer layer for imprinting which satisfies at least one of A and B.

A: A component having a surface tension of greater than or equal to 40 mN/m at 25° C. is contained.

B: A critical surface tension of a primer layer formed from the composition for forming a primer layer for imprinting is greater than or equal to 46 mN/m at 25° C.

<2> The composition for forming a primer layer for imprinting according to <1>, in which the component having a surface tension of greater than or equal to 40 mN/m at 25° C. is contained in a component constituting the primer layer in a proportion of greater than or equal to 20 mass %.

<3> The composition for forming a primer layer for imprinting according to <1> or <2> which contains a compound having a polyalkylene glycol structure including a linear alkylene group and an oxygen atom.

<4> The composition for forming a primer layer for imprinting according to <3>, in which the compound having the polyalkylene glycol structure including the linear alkylene group and the oxygen atom is the component having a surface tension at 25° C. of greater than or equal to 40 mN/m.

<5> The composition for forming a primer layer for imprinting according to <1> or <2> which contains a compound having a polyethylene glycol structure.

<6> The composition for forming a primer layer for imprinting according to <5>, in which the compound having a polyethylene glycol structure is the component having a surface tension of greater than or equal to 40 mN/m at 25° C.

<7> The composition for forming a primer layer for imprinting according to any one of <1> to <6>, in which at least one kind of the component having a surface tension of greater than or equal to 40 mN/m at 25° C. does not have a polymerizable group.

<8> The composition for forming a primer layer for imprinting according to any one of <1> to <7>, in which at least one kind of the component having a surface tension of greater than or equal to 40 mN/m at 25° C. is a liquid at 25° C.

<9> The composition for forming a primer layer for imprinting according to any one of <1> to <8>, in which greater than or equal to 95 mass % of the component which constitutes the primer layer and is contained in the composition for forming a primer layer for imprinting is a liquid at 25° C.

<10> The composition for forming a primer layer for imprinting according to any one of <1> to <9>, in which a weight-average molecular weight of the component having a surface tension of greater than or equal to 40 mN/m at 25° C. is greater than or equal to 200 and less than 1,000.

<11> A primer layer for imprinting, in which a critical surface tension at 25° C. is greater than or equal to 46 mN/m.

<12> The primer layer for imprinting according to <11> which is formed of the composition for forming a primer layer for imprinting according to any one of <1> to <10>.

<13> The primer layer for imprinting according to <11> or <12>, in which a thickness is less than or equal to 10 nm.

<14> A laminate comprising: the primer layer for imprinting according to any one of <11> to <13>; and a layer which is formed of a curable composition for imprinting and positioned on a surface of the primer layer for imprinting.

<15> The laminate according to <14>, further comprising: an adhesive layer on a surface of the primer layer for imprinting on an opposite side to the side where the layer formed of the curable composition for imprinting is positioned.

According to the present invention, it has become possible to improve the wettability of a curable composition for imprinting on a substrate.

Specifically, it has become possible to provide a novel composition for forming a primer layer for imprinting, a primer layer for imprinting, and a laminate.

### BRIEF DESCRIPTION OF THE DRAWINGS

FIG. 1 is a schematic view showing each step of a pattern forming method of the present invention.

FIG. 2 is a schematic view showing a state of wet-spreading of a curable composition for imprinting in a case where a surface of a well-known adhesive layer is coated with a curable composition for imprinting through an inkjet method.

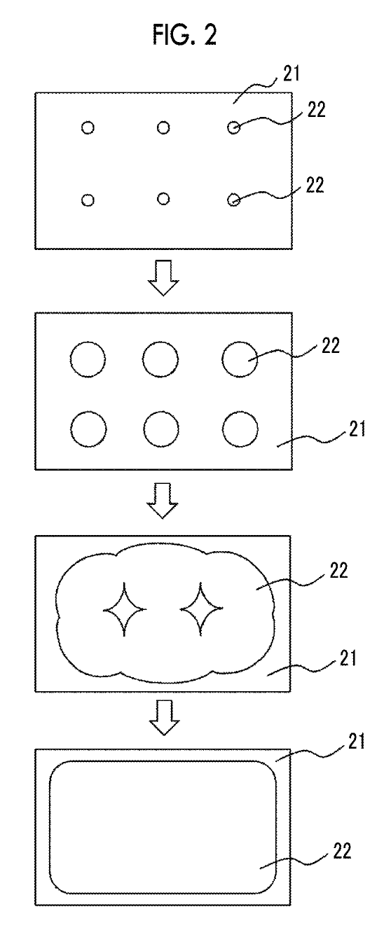

### DESCRIPTION OF THE PREFERRED EMBODIMENTS

Hereinafter, the contents of the present invention will be described in detail. In the present specification, “to” means a range including numerical values denoted before and after “to” as a lower limit value and an upper limit value.

In the present specification, “(meth)acrylate” represents acrylate and methacrylate.

In the present specification, “imprinting” preferably refers to transferring a pattern with a size of 1 nm to 10 mm, and more preferably to transferring (nanoimprinting) a pattern with a size of about 10 nm to 100 μm.

In the notation of a group (atomic group) in the present specification, in a case where it is not described whether the group is substituted or unsubstituted, the group is meant to include and not to include a substituent. For example, an “alkyl group” includes not only an alkyl group having no substituent (unsubstituted alkyl group), but also an alkyl group having a substituent (substituted alkyl group).

In the present specification, “light” includes not only electromagnetic waves or light with a wavelength in regions such as an ultraviolet region, a near ultraviolet region, a far ultraviolet region, a visible region, or an infrared region, but also radiation. Radiation includes, for example, microwaves, electron beams, extreme ultraviolet rays (EUV), and X-rays. In addition, laser beams such as a 248 nm excimer laser, a 193 nm excimer laser, and a 172 nm excimer laser can also be used. For these light beams, monochromatic light (single-wavelength light) passed through an optical filter may be used, or light with a plurality of different wavelengths (composite light) may be used.

The weight-average molecular weight (Mw) in the present invention is measured through gel permeation chromatography (GPC) unless otherwise specified.

A composition for forming a primer layer for imprinting (hereinafter, sometimes simply referred to as a “composition for forming a primer layer”) satisfies at least one of A and B.

A: A component having a surface tension of greater than or equal to 40 mN/m at 25° C. is contained.

B: A critical surface tension of a primer layer (hereinafter, sometimes simply referred to as a “primer layer”) formed of the composition for forming a primer layer for imprinting is greater than or equal to 46 mN/m at 25° C.

Here, the composition for forming a primer layer for imprinting of the present invention is a composition constituting the primer layer which becomes an underlayer onto which a curable composition for imprinting is to be applied. That is, the curable composition for imprinting is applied to a surface of the primer layer. The primer layer is usually provided on a surface of an adhesive layer as will be described below.

By adopting such a configuration, it is possible to improve wettability of the curable composition for imprinting. In addition, the surface roughness of the primer layer can be reduced. Furthermore, it is possible to keep a release force of a pattern obtained from the curable composition for imprinting small. In addition, a pattern having excellent pattern formability can be formed.

The primer layer formed of the composition for forming a primer layer is usually a liquid film, but may be a solid film within the scope not departing from the gist of the present invention.

The component having a surface tension of greater than or equal to 40 mN/m at 25° C. in the present invention preferably has a surface tension of 40 to 70 mN/m. By adopting such a configuration, it is possible to improve the wettability of the curable composition for imprinting to be applied to the surface of the primer layer and to enhance filling properties. The surface tension is measured according to a method to be described in examples below.

In addition, in the present invention, the critical surface tension of the primer layer is preferably greater than or equal to 46 mN/m. By adopting such a configuration, it is possible to improve the wettability of the curable composition for imprinting to be applied to the surface of the primer layer and to enhance filling properties. The critical surface tension is measured according to a method to be described in examples below.

In the present invention, the critical surface tension of the primer layer formed of the composition for forming a primer layer preferably has a lower limit value of greater than or equal to 47 mN/m, and more preferably greater than or equal to 48 mN/m. The upper limit value of the critical surface tension of the primer layer is not particularly limited, but is preferably less than or equal to 70 mN/m. The upper limit value thereof may be less than or equal to 65 mN/m or less than or equal to 60 mN/m.

The composition for forming a primer layer preferably contains a component having a surface tension of greater than or equal to 40 mN/m at 25° C. in a component constituting the primer layer in a proportion of greater than or equal to 20 mass %, more preferably in a proportion of greater than or equal to 51 mass %, still more preferably in a proportion of greater than or equal to 80 mass %, still more preferably in a proportion of greater than or equal to 90 mass %, still more preferably in a proportion of greater than or equal to 95 mass %, and still more preferably in a proportion of greater than or equal to 99 mass %.

The composition for forming a primer layer may contain only one kind of component having a surface tension of greater than or equal to 40 mN/m at 25° C. or may contain two or more kinds of components having a surface tension of greater than or equal to 40 mN/m at 25° C. In a case where the composition for forming a primer layer contains two or more kinds thereof, the total amount is preferably within the above-described ranges.

The present invention preferably contains a compound (hereinafter, sometimes simply referred to as “PEG or the like”) having a polyalkylene glycol structure including a linear alkylene group and an oxygen atom as the component constituting a primer layer. The linear alkylene group is preferably an alkylene group having 1 to 10 carbon atoms, more preferably an alkylene group having 1 to 5 carbon atoms, still more preferably an alkylene group having 1 to 3 carbon atoms, still more preferably an alkylene group having 2 or 3 carbon atoms, and still more preferably an alkylene group having 2 carbon atoms. That is, the component constituting a primer layer in the present invention preferably contains a compound having a polyethylene glycol structure.

PEG or the like preferably contains 3 to 50 alkylene glycol units. PEG or the like may be a component having a surface tension of greater than or equal to 40 mN/m at 25° C. or a component having a surface tension of less than 40 mN/m at 25° C., but is preferably a component having a surface tension of greater than or equal to 40 mN/m at 25° C.

In a case where PEG or the like is a component having a surface tension of greater than or equal to 40 mN/m at 25° C., PEG or the like preferably contains 3 to 20 alkylene glycol units and more preferably contains 5 to 17 alkylene glycol units.

In a case where the critical surface tension of the primer layer at 25° C. is greater than or equal to 46 mN/m, the composition for forming a primer layer preferably contains a compound, which has a polyalkylene glycol structure including a linear alkylene group and an oxygen atom and contains 21 to 50 alkylene glycol units, as a component constituting the primer layer, and more preferably contains a compound, which has a polyalkylene glycol structure including a linear alkylene group and an oxygen atom and contains 22 to 45 alkylene glycol units, as a component constituting the primer layer.

PEG or the like may contain structures other than the polyalkylene glycol structure. However, PEG or the like preferably has a polyalkylene glycol structure excluding a terminal group. That is, it is preferable that PEG or the like is represented by “terminal group—polyalkylene glycol structure including linear alkylene group and oxygen atom—terminal group”. The terminal group here is preferably a hydrogen atom, a hydroxyl group, an alkyl group, or an alkoxy group. The number of carbon atoms of an alkyl group and the number of carbon atoms of an alkyl chain of an alkoxy group are preferably 1 to 3, more preferably 1 or 2, and still more preferably 1.

Specific examples of PEG or the like include compounds A-1 to A-6 and A-9 used in examples to be described below.

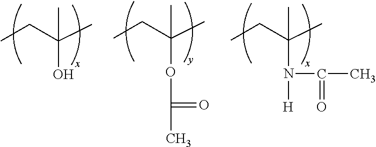

In the present invention, as described above, it is preferable that at least one kind of component constituting the primer layer has: a component constituting an adhesive layer; and a functional group capable of forming at least one of a hydrogen bond or an interionic interaction. Such a functional group is preferably included in a component having a surface tension of greater than or equal to 40 mN/m at 25° C. Preferably, in a case where the component having a surface tension of greater than or equal to 40 mN/m at 25° C. is PEG or the like, it is preferable that one or both of the terminal groups are a component constituting an adhesive layer and a functional group (preferably a hydroxyl group, an amino group, a carbonyl group, a carboxyl group, or the like, and more preferably a hydroxyl group) capable of forming at least one of a hydrogen bond or an interionic interaction.

In the present invention, the component having a surface tension of greater than or equal to 40 mN/m at 25° C. may be a compound other than PEG or the like. Examples thereof include polyhydric alcohol such as glycerol, and ionic polymers such as polyvinyl alcohol, polyvinyl acetamide, and polystyrene sulfonic acid.

In addition, in the present invention, an aspect is exemplified in which the composition for forming a primer layer contains: PEG or the like having a surface tension of less than 40 mN/m at 25° C.; and a component having a surface tension of greater than or equal to 40 mN/m at 25° C. other than PEG or the like.

In the present invention, it is preferable that at least one kind (preferably all) of the component having a surface tension of greater than or equal to 40 mN/m at 25° C. has a polymerizable group. By adopting such a configuration, it is possible to further improve mold releasability.

In the present invention, it is preferable that at least one kind of the component having a surface tension of greater than or equal to 40 mN/m at 25° C. is a liquid at 25° C. In addition, it is more preferable that greater than or equal to 95 mass % (preferably greater than or equal to 98 mass % and more preferably greater than or equal to 99 mass %) of the component constituting a primer layer is a liquid at 25° C. It is possible to more effectively reduce the surface roughness of the primer layer using the liquid.

In the present invention, at least one kind of the component having a surface tension of greater than or equal to 40 mN/m at 25° C. preferably has a weight-average molecular weight of greater than or equal to 200 and less than 1,000 and more preferably a weight-average molecular weight of greater than or equal to 300 and less than 800. By adopting such a configuration, the compatibility between the component constituting a primer layer and the curable composition for imprinting improves.

The component constituting a primer layer may contain a polymerizable compound in addition to the above.

The polymerizable compound may be a monofunctional polymerizable compound or a polyfunctional polymerizable compound, and is preferably a polyfunctional polymerizable compound, more preferably a bi- to tetrafunctional polymerizable compound, and still more preferably a bi- or tri-functional polymerizable compound. Specific examples of the polymerizable compound include a polymerizable compound which may be contained in a curable composition for imprinting to be described below. Particularly, B-1 to B-3 used in examples to be described below are preferable.

Among the components constituting a primer layer, an upper limit value of the content of the polymerizable compound is preferably less than or equal to 50 mass % and more preferably less than or equal to 20 mass %. In addition, the above-described lower limit value of the content of the polymerizable compound is preferably greater than or equal to 10 mass % in a case of being formulated.

The composition for forming a primer layer may contain only one kind of polymerizable compound or two or more kinds of polymerizable compounds. In a case where the composition for forming a primer layer contains two or more kinds thereof, the total amount is preferably within the above-described ranges.

In the present invention, the composition for forming a primer layer preferably contains a solvent. In a case where the composition for forming a primer layer contains a solvent, it is possible to perform coating. The solvent is preferably a solvent having any one of an ester group, a carbonyl group, a hydroxyl group, or an ether group. Specific examples of preferred solvents include propylene glycol monomethyl ether acetate (PGMEA), ethoxyethyl propionate, cyclohexanone, 2-heptanone, y-butyrolactone, butyl acetate, propylene glycol monomethyl ether, and ethyl lactate. Among these, PGEMA, γ-butyrolactone, and cyclohexanone are more preferable, and PGMEA is particularly preferable.

A solvent contained in a composition for forming an adhesive layer and a solvent contained in a composition for forming a primer layer are preferably solvents different from each other.

In the present invention, the composition for forming a primer layer preferably contains 0.001 to 2.0 mass % of the component constituting a primer layer and 98.0 to 99.999 mass % of a solvent, and more preferably contains 0.05 to 0.5 mass % of the component constituting a primer layer and 99.5 to 99.95 mass % of a solvent. The component constituting a primer layer preferably contain a component having a surface tension of greater than or equal to 40 mN/m at 25° C., and more preferably contain a component having a surface tension of greater than or equal to 40 mN/m at 25° C. in a proportion of greater than or equal to 99 mass %.

One kind or two or more kinds of each of the components constituting a primer layer and the solvents may be contained in the composition for forming a primer layer. In a case where the composition for forming a primer layer contains two or more kinds thereof, the total amount is preferably within the above-described ranges.

The composition for forming a primer layer of the present invention is used for forming an imprint pattern.

As a pattern forming method, there is a preferred aspect of including: a step of forming a primer layer, which has a critical surface tension higher than that of an adhesive layer positioned on a substrate, on the surface of the above-described adhesive layer; and a step of applying a curable composition for imprinting onto the surface of the above-described primer layer. By adopting such a configuration, the curable composition for imprinting can spread on the surface of the primer layer in a short period of time or easily and to improve the filling properties of the curable composition for imprinting on a substrate.

In the present invention, there is disclosed a laminate: including the primer layer including the composition for forming a primer layer of the present invention; and a layer which is formed of a curable composition for imprinting and positioned on the surface of the above-described primer layer. Furthermore, the laminate preferably includes an adhesive layer on a surface of the primer layer on an opposite side to the side where the layer formed of the curable composition for imprinting is positioned. In addition, it is preferable that the thickness of the above-described primer layer is less than or equal to 10 nm.

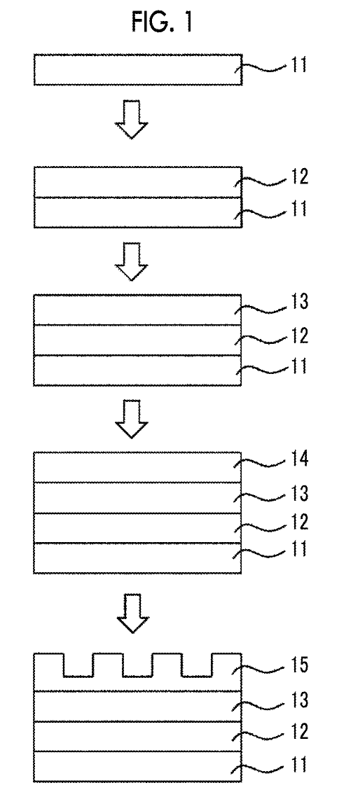

Hereinafter, the method for forming a pattern (pattern forming method) using the composition for forming a primer layer of the present invention will be described with reference to FIG. 1. Needless to say, the configuration of the present invention is not limited to FIG. 1.

<Step of Forming Adhesive Layer on Substrate>

In the present invention, a primer layer may be formed directly on the surface of a substrate, but is preferably formed on the surface of an adhesive layer provided on a substrate. Accordingly, the pattern forming method of the present invention preferably includes a step of forming an adhesive layer on a substrate. However, in a case of using a prepared substrate with an adhesive layer formed thereon in advance, this step is not always indispensable.

In the embodiment shown in FIG. 1, an adhesive layer 12 is formed on a substrate 11. Although the adhesive layer 12 is formed on the surface of the substrate 11 in FIG. 1, another layer may be formed between the substrate 11 and the adhesive layer 12. For example, a case where the surface of the substrate 11 is subjected to a surface treatment is conceivable.

The material of the substrate is not particularly limited, and a disclosure of paragraph 0103 of JP 2010-109092A (corresponding US application is US2011/0199592) can be referred to, and the contents thereof are incorporated in the present specification. In addition to the above, examples thereof include a sapphire substrate, a silicon carbide substrate, a gallium nitride substrate, an aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Examples of specific materials of a glass substrate include aluminosilicate glass, aluminoborosilicate glass, and barium borosilicate glass. In the present invention, a silicon substrate is preferable.

In the present invention, the critical surface tension of an adhesive layer at 25° C. is preferably greater than or equal to 30 mN/m and more preferably greater than or equal to 40 mN/m. The upper limit value is not particularly limited, but is, for example, less than or equal to 70 mN/m and preferably less than or equal to 60 mN/m. The critical surface tension of the present specification is measured according to a method to be described in examples below.

The lower limit value of the thickness of an adhesive layer is preferably greater than or equal to 0.1 nm, more preferably greater than or equal to 0.5 nm, and still more preferably greater than or equal to 1 nm. In addition, the upper limit value of the thickness of an adhesive layer is preferably less than or equal to 20 nm, more preferably less than or equal to 15 nm, and still more preferably less than or equal to 10 nm.

The adhesive layer is usually formed by applying a composition for forming an adhesive layer onto a substrate. More specifically, after applying a composition for forming an adhesive layer onto a substrate, a solvent is volatilized (dried) using heat or through light irradiation, and/or the adhesive layer is hardened to form a thin film. The method for applying a composition for forming an adhesive layer is not particularly limited, and a disclosure of paragraph 0102 of JP 2010-109092A (corresponding US application is US2011/0199592) can be referred to, and the contents thereof are incorporated in the present specification. In the present invention, a spin coating method or an inkjet method is preferable.

A composition containing a solvent and a component constituting an adhesive layer is preferable as the composition for forming an adhesive layer.

The component constituting an adhesive layer is preferably a resin, more preferably a resin containing an ethylenically unsaturated group, and still more preferably an acrylic resin having an ethylenically unsaturated group in a side chain. Specific examples of a resin as a component constituting an adhesive layer include resins (A) and (A2) disclosed in paragraphs 0017 to 0057 disclosed in JP2014-024322A. The weight-average molecular weight of a resin is preferably 3,000 to 25,000. In addition, the component constituting an adhesive layer may contain an additive in addition to the resin. However, in the component constituting an adhesive layer of the present invention, it is preferable that greater than or equal to 70 mass % is a resin and it is more preferable that greater than or equal to 80 mass % is a resin.

In order to secure the stability of a primer layer, at least one kind of the component constituting an adhesive layer preferably includes: a component constituting a primer layer; and a functional group capable of forming at least one of a hydrogen bond or an interionic interaction. Examples of the above-described functional group include a hydroxyl group, an amino group, a carbonyl group, and a carboxyl group. Such a functional group is preferably included in the resin.

By adopting such a configuration, an adhesive layer is fixed to a primer layer by a hydrogen bond and/or an interionic interaction. For this reason, it is possible to suppress planar roughness such as aggregation by securing coating uniformity of the primer layer. In addition, it is possible to more effectively suppress the component constituting an adhesive layer from moving to the primer layer, a curable composition for imprinting which is provided as an upper layer on the primer layer, or a pattern which is a hardened product of the curable composition for imprinting. As a result, a substance which can increase the fixing force between the pattern and a mold is less likely to be present in the vicinity of the pattern, and therefore, it is possible to improve the mold releasability of the pattern.

The component constituting an adhesive layer means a component contained in an adhesive layer. For example, a component obtained by removing a solvent from the above-described composition for forming an adhesive layer corresponds thereto. Similarly, the component constituting a primer layer means a component contained in a primer layer. For example, a component obtained by removing a solvent from a composition for forming a primer layer correspond thereto.

In addition, in the present invention, it is preferable that at least one kind (preferably all) of the component constituting an adhesive layer are substantially insoluble in the solvent contained in the composition for forming a primer layer. By adopting such a constitution, in a case where a primer layer is formed, it is difficult for a component constituting an adhesive layer to be incorporated into the primer layer, and deterioration of the mold releasability of a pattern does not occur. Being substantially insoluble means that a component of an adhesive layer which is eluted in a primer layer at the time of forming the primer layer is less than or equal to 10 mass % of total components forming the primer layer. By adopting such a configuration, it is possible to effectively suppress deterioration of the releasability of a mold.

In the present invention, it is preferable that the component constituting an adhesive layer is a component which does not substantially thermally diffuse into the primer layer. After a primer layer is formed on the surface of an adhesive layer, in some cases, the adhesive layer may be heated together with the primer layer or the like. However, in a case where a component constituting an adhesive layer thermally diffuses in such a heating step, in some cases, the mold releasability of a pattern may deteriorate similarly to the above. In the present invention, such a point is avoided using components which do not substantially thermally diffuse into the primer layer, as the component constituting an adhesive layer. Not being substantially thermally diffusing means that a component of an adhesive layer which is eluted in a primer layer after forming the primer layer is less than or equal to 10 mass % of total components forming the primer layer. By adopting such a configuration, it is possible to effectively suppress deterioration of the releasability of a mold.

Examples of the heating in the present invention include: heating for drying a solvent contained in a composition for forming a primer layer in a case of forming a primer layer; or heating for enhancing the reactivity of a curable composition for imprinting in a case of subjecting the curable composition for imprinting to light irradiation. The heating temperature is, for example, 50° C. to 200° C. and preferably 80° C. to 150° C.

Solvents described in paragraph 0059 of JP2014-024322A are exemplified as solvents which may be formulated with a composition for forming an adhesive layer, and the contents thereof are incorporated in the present specification.

In addition, the composition for forming an adhesive layer used in the present invention preferably contains 0.001 to 2.0 mass % of a component constituting an adhesive layer and 98.0 to 99.999 mass % of a solvent, and more preferably contains 0.05 to 0.5 mass % of a component constituting an adhesive layer and 99.5 to 99.95 mass % of a solvent.

One kind or two or more kinds of each of the components constituting an adhesive layer and the solvents may be contained in the composition for forming an adhesive layer. In a case where the composition for forming an adhesive layer contains two or more kinds thereof, the total amount is preferably within the above-described ranges.

A specific example of the composition for forming an adhesive layer includes a composition for forming an underlayer film for imprinting containing: a solvent (B) and a (meth)acrylic resin (A) which has an ethylenically unsaturated group (P) and a nonionic hydrophilic group (Q) and has a weight-average molecular weight of greater than or equal to 1,000, in which an acid value of the above-described resin (A) is less than 1.0 mmol/g, the composition for forming an underlayer film for imprinting being disclosed in JP2014-024322A. The contents of JP2014-024322A are incorporate into the present specification.

In addition, the disclosure of JP2014-024322A can also be referred to for a method for preparing a composition for forming an adhesive layer, a method for forming an adhesive layer using the above-described composition for forming an adhesive layer, and the like. The contents thereof are incorporate into the present specification.

<Step of Forming Primer Layer Having Critical Surface Tension Higher than that of Adhesive Layer on Surface of Above-Described Adhesive Layer>

In the present invention, it is preferable that a primer layer 13 having a critical surface tension higher than that of the adhesive layer 12 is formed on the surface of the adhesive layer. By forming such a primer layer, it is possible to improve the filling properties of the curable composition for imprinting on a substrate.

The critical surface tension of a primer layer at 25° C. is preferably higher than that of an adhesive layer, more preferably higher than that of an adhesive layer by 2 mN/m or more, still more preferably higher than that of an adhesive layer by 3 mN/m or more, and still more preferably higher than that of an adhesive layer by 5 mN/m or more. The upper limit value of the difference in the critical surface tension between the primer layer and the adhesive layer is preferably less than or equal to 20 mN/m, more preferably less than or equal to 15 mN/m, and still more preferably less than or equal to 10 mN/m. By setting the upper limit value thereof to be within the above-described ranges, the effect of improving the uniformity and the wettability of a film at the time of forming a primer layer is more effectively enhanced.

The lower limit value of the thickness of a primer layer is preferably greater than or equal to 0.1 nm, more preferably greater than or equal to 0.5 nm, and still more preferably greater than or equal to 1 nm. In addition, the upper limit value of the thickness of a primer layer is preferably less than or equal to 20 nm, more preferably less than or equal to 15 nm, and still more preferably less than or equal to 10 nm.

In the present invention, the primer layer is usually formed using a composition for forming a primer layer. The composition for forming a primer layer preferably contains a solvent. Specifically, after applying the composition for forming a primer layer onto the surface of an adhesive layer, a solvent is volatilized using heat or through light irradiation to form a thin film. The method for applying a composition for forming a primer layer is not particularly limited, and a disclosure of paragraph 0102 of JP 2010-109092A (corresponding US application is US2011/0199592) can be referred to, and the contents thereof are incorporated in the present specification. In the present invention, a spin coating method or an inkjet method is preferable.

In a case where the composition for forming an adhesive layer which contains a solvent is used in a case of forming an adhesive layer, a primer layer is preferably formed by applying a composition for forming a primer layer after volatilizing (drying) the solvent from the composition for forming an adhesive layer and/or after hardening the adhesive layer. By adopting such a configuration, it is possible to effectively suppress an adhesive layer and a primer layer from being mixed with each other due to a component constituting the primer layer dissolving in a solvent contained in a composition for forming an adhesive layer.

In addition, a method for preparing a composition for forming a primer layer, a method for forming a primer layer formed of the above-described composition for forming a primer layer, and the like can be performed similarly to the method for preparing a composition for forming an adhesive layer and the method for forming an adhesive layer.

It is particularly preferable that the present invention includes forming of a primer layer using a composition for forming a primer layer containing a solvent, in which the above-described component constituting an adhesive layer are not substantially insoluble in the solvent contained in the composition for forming a primer layer. By adopting such a configuration, it is possible to more effectively suppress the deterioration of the mold releasability caused by incorporation of the component of the adhesive layer into the primer layer.

In addition, in the present invention, at least one kind of the component constituting a primer layer preferably includes: a component constituting an adhesive layer; and a functional group capable of forming at least one of a hydrogen bond or an interionic interaction. Examples of the functional group which may be included in the component constituting a primer layer include a hydroxyl group, an amino group, a carbonyl group, and a carboxyl group, and a hydroxyl group is preferable.

In addition, it is preferable that greater than or equal to 95 mass % (preferably greater than or equal to 98 mass % and more preferably greater than or equal to 99 mass %) of the component constituting a primer layer is a liquid at 25° C., and the contact angles of the above-described component constituting a primer layer on the surface of the above-described adhesive layer at 25° C. 10 seconds after dropwise addition are less than or equal to 5°. The contact angles are measured according to a method to be described in examples below. By adopting such a configuration, it is possible to form a primer layer uniformly on an adhesive layer and to make the filling properties of a curable composition for imprinting more uniform.

Furthermore, it is preferable that the component constituting a primer layer is compatible with the curable composition for imprinting. Here, the compatibility means that a component constituting a primer layer is sufficiently dissolved in a curable composition for imprinting, and there is no clear interface existing between the primer layer and the curable composition for imprinting. In the case where the primer layer is compatible with the curable composition for imprinting in this manner, it is possible to effectively suppress occurrence of peeling-off defects or the like during release, due to close attachment with an adhesive layer caused by diffusion of a part of the curable composition for imprinting in the primer layer at the time of filling with the curable composition for imprinting.

<Step of Applying Curable Composition for Imprinting onto Surface of Primer Layer>

The present invention includes a step of applying a curable composition for imprinting 14 onto the surface of the primer layer 13 as shown in FIG. 1. The method for applying a curable composition for imprinting is not particularly limited, and a disclosure of paragraph 0102 of JP 2010-109092A (corresponding US application is US2011/0199592) can be referred to, and the contents thereof are incorporated in the present specification. The above-described application is preferably performed through an inkjet method. In addition, the curable composition for imprinting may be applied through multiple coating. In a method for disposing liquid droplets on the surface of a primer layer through an inkjet method or the like, the amount of liquid droplets is preferably about 1 to 20 pL, and the liquid droplets are preferably disposed on the surface of the primer layer at intervals between the liquid droplets. As the intervals between the liquid droplets, intervals of 10 to 1,000 μm are preferable. In the case of the inkjet method, the intervals between the liquid droplets are set as intervals at which inkjet nozzles are disposed.

Furthermore, the volume ratio of the layer-shaped curable composition for imprinting 14 to the primer layer 13 when applied on the substrate is preferably 1:1 to 500, more preferably 1:10 to 300, and still more preferably 1:50 to 200.

<Formation of Pattern>

It is preferable that the pattern forming method to be performed in the present invention further includes: a step of subjecting a curable composition for imprinting, a primer layer, and an adhesive layer to light irradiation in a state in which these are interposed between a substrate and a mold having a pattern to harden the curable composition for imprinting; and a step of peeling the mold. Through such steps, a pattern 15 is obtained as shown in FIG. 1, for example.

Specifically, in order to transfer a desired pattern to a layer-shaped curable composition for imprinting, a mold is brought into press contact with the surface of the layer-shaped curable composition for imprinting. Accordingly, it is possible to transfer a fine pattern previously formed on the pressing surface of the mold to the layer-shaped curable composition for imprinting.

The mold may be a light-transmitting mold or a light non-transmitting mold. In a case where a light-transmitting mold is used, it is preferable to radiate light from the mold side. On the other hand, in a case where a light non-transmitting mold is used, it is preferable to use a light-transmitting substrate as a substrate to radiate light from the substrate side. In the present invention, it is preferable to radiate light from a mold side using a light-transmitting mold.

A mold which can be used in the present invention is a mold having a pattern to be transferred. Regarding the pattern on the above-described mold, it is possible to form a pattern according to a desired processing accuracy, for example, through photolithography, or an electron beam drawing method. In the present invention, the mold pattern forming method is not particularly limited. In addition, it is possible to use a pattern formed through the above-described pattern forming method as a mold.

Materials constituting the light-transmitting mold used in the present invention are not particularly limited, examples thereof include glass, quartz, polymethyl methacrylate (PMMA), a light-transmitting resin such as a polycarbonate resin, a transparent metal vapor deposition film, a flexible film such as polydimethylsiloxane, a photocured film, and a metal film.

Materials of the light non-transmitting mold used in a case where a light-transmitting substrate of the present invention is used are not particularly limited, but may have a predetermined strength. Specific examples thereof include a ceramic material, an vapor deposition film, a magnetic film, a reflective film, a metal substrate of Ni, Cu, Cr, Fe or the like, a substrate of SiC, silicon, silicon nitride, polysilicon, silicon oxide, amorphous silicon, or the like, but are not particularly restricted.

In the above-described pattern forming method, in a case where imprint lithography is performed using a curable composition for imprinting, it is preferable to set the mold pressure to be less than or equal to 10 atm. By setting the mold pressure to be lower than or equal to 10 atm, it is difficult for a mold and a substrate to deform, and the pattern accuracy tends to improve. In addition, it is preferable from the viewpoint that the size of a device tends to be reduced due to low pressurization. The mold pressure is preferably selected from a range within which the uniformity of mold transfer can be secured within a range where a residual film of a curable composition for imprinting of a mold convex portion is reduced.

In the pattern forming method, the irradiation amount of light irradiation in the above-described step of irradiating the curable composition for imprinting with light may be sufficiently larger than the minimum irradiation amount necessary for hardening. The irradiation amount necessary for hardening is appropriately determined by investigating the amount of consumption of unsaturated bonds of the curable composition for imprinting or the like.

In addition, regarding the temperature of a substrate in a case of light irradiation in imprint lithography applied to the present invention, light irradiation is usually performed at room temperature, but may be performed while heating in order to enhance the reactivity. In a case where the environment is kept in a vacuum condition as a preliminary stage of light irradiation, it is effective to prevent air bubbles from being mixed in, suppress a decrease in reactivity due to oxygen mixed in, and improve the adhesiveness between a mold and a curable composition for imprinting. Therefore, light irradiation may be performed in a vacuum condition. In addition, in the pattern forming method, the preferred degree of vacuum at the time of light irradiation is within a range of 10⁻¹ Pa to an atmospheric pressure.

In a case of exposure, it is desirable to set the exposure illuminance to be within a range of 1 mW/cm² to 500 mW/cm².

The above-described pattern forming method may include a step of hardening a layer-shaped curable composition for imprinting (pattern forming layer) through light irradiation, and then, further hardening the hardened pattern by adding heat as necessary. The temperature for heating and hardening a curable composition for imprinting after light irradiation is preferably 150° C. to 280° C. and more preferably 200° C. to 250° C. In addition, the time for applying heat is preferably 5 to 60 minutes and more preferably 15 to 45 minutes.

Next, the curable composition for imprinting used in the present invention will be described.

The curable composition for imprinting used in the present invention is not particularly limited, and a well-known curable composition for imprinting can be used.

In the present invention, it is preferable that the viscosity of the curable composition for imprinting is designed to be low and the surface tension is designed to be high so as to enable high-speed filling using a capillary force.

Specifically, the viscosity of the curable composition for imprinting at 23° C. is preferably less than or equal to 20.0 mPa·s, more preferably less than or equal to 15.0 mPa·s, still more preferably less than or equal to 10.0 mPa·s, and still more preferably less than or equal to 8.0 mPa·s. The lower limit value of the above-described viscosity is not particularly limited, but can be set to be, for example, greater than or equal to 5.0 mPa s.

In addition, the surface tension of the curable composition for imprinting at 25° C. is preferably greater than or equal to 30 mN/m and more preferably greater than or equal to 33 mN/m. In a case where a curable composition for imprinting with a high surface tension is used, the capillary force increases, which enables high-speed filling of a mold pattern with the curable composition for imprinting. The upper limit value of the above-described surface tension is not particularly limited, but is preferably less than or equal to 40 mN/m from the viewpoint of imparting inkjet suitability.

In the present invention, use of a primer layer is highly meaningful from the viewpoint of improving wettability of a curable composition for imprinting with a high surface tension which has poor wettability on an adhesive layer while having a high capillary force and good filling properties in a mold pattern.

The surface tension of curable composition for imprinting at 25° C. is measured according to a method to be described in examples below.

The type or the like of the curable composition for imprinting used in the present invention is not particularly specified, but it is preferable that the curable composition for imprinting includes a polymerizable compound and a photopolymerization initiator. Furthermore, the curable composition for imprinting may contain a sensitizer, a releasing agent, an antioxidant, a polymerization inhibitor, a solvent, and the like.

The polymerizable compound contained in the curable composition for imprinting used in the present invention may be a monofunctional polymerizable compound or a polyfunctional polymerizable compound, or a mixture of both compounds. In addition, at least a part of the polymerizable compound contained in the curable composition for imprinting is preferably a liquid at 25° C. In a case where the curable composition for imprinting contains a polymerizable compound in this manner which is a liquid at 25° C., even if the curable composition for imprinting does not substantially contain a solvent, it is possible to reduce the viscosity of the curable composition for imprinting to make the curable composition for imprinting applicable through an inkjet method. Here, the expression “does not substantially contain a solvent” means, for example, that the content of a solvent with respect to the curable composition for imprinting is less than or equal to 5 mass %, more preferably less than or equal to 3 mass %, particularly preferably less than or equal to 1 mass %.

In addition, it is possible to employ an aspect in which the curable composition for imprinting used in the present invention does not substantially contain a polymer (polymer having a weight-average molecular weight of preferably greater than 1,000, more preferably greater than 2,000, and still more preferably greater than or equal to 10,000). The expression “does not substantially contain a polymer” means, for example, that the content of a polymer is less than or equal to 0.01 mass % of the curable composition for imprinting and preferably less than or equal to 0.005 mass %. It is more preferable that the curable composition for imprinting contains no polymer.

The type of monofunctional polymerizable compound used in the curable composition for imprinting is not particularly defined as long as the type thereof does not depart from the gist of the present invention.

The monofunctional polymerizable compound used in the curable composition for imprinting preferably has a linear or branched hydrocarbon chain having 4 or more carbon atoms. Only one kind or two or more kinds of monofunctional polymerizable compounds may be contained in the present invention.

The molecular weight of the monofunctional polymerizable compound used in the curable composition for imprinting is preferably greater than or equal to 100, more preferably greater than or equal to 200, and still more preferably greater than or equal to 220. The upper limit value of the molecular weight is preferably less than or equal to 1,000, more preferably less than or equal to 800, still more preferably less than or equal to 300, and particularly preferably less than or equal to 270. In a case where the lower limit value of the molecular weight is set to be greater than or equal to 200, there is a tendency that it is possible to suppress the volatility. In a case where the upper limit value of the molecular weight is set to be less than or equal to 300, there is a tendency that it is possible to reduce the viscosity.

The boiling point of the monofunctional polymerizable compound used in the curable composition for imprinting at 667 Pa is preferably greater than or equal to 85° C., more preferably greater than or equal to 110° C., and still more preferably greater than or equal to 130° C. By setting the boiling point at 667 Pa to be greater than or equal to 85° C., it is possible to suppress the volatility. The upper limit value of the boiling point is not particularly specified, but the boiling point at 667 Pa can be set, for example, to be less than or equal to 200° C.

The kind of polymerizable group included in the monofunctional polymerizable compound used in the curable composition for imprinting is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloyl group, and still more preferably an acryloyl group. In addition, the (meth)acryloyl group is preferably a (meth)acryloyloxy group.

The kinds of atoms constituting the monofunctional polymerizable compound used in the curable composition for imprinting is not particularly specified, but the monofunctional polymerizable compound thereof is preferably constituted of only atoms selected from carbon atoms, oxygen atoms, hydrogen atoms, and halogen atoms, and is more preferably constituted of only atoms selected from carbon atoms, oxygen atoms, and hydrogen atoms.

The monofunctional polymerizable compound used in the curable composition for imprinting preferably has a linear or branched hydrocarbon chain having 4 or more carbon atoms. The hydrocarbon chain in the present invention represents an alkyl chain, an alkenyl chain, and an alkanol chain, preferably an alkyl chain and an alkenyl chain, and more preferably an alkyl chain.

In the present invention, the alkyl chain represents an alkyl group and an alkylene group. Similarly, the alkenyl chain represents an alkenyl group and an alkenylene group, and the alkynyl chain represents an alkynyl group and an alkynylene group. Among these, a linear or branched alkyl group or alkenyl group is more preferable, a linear or branched alkyl group is still more preferable, and a linear alkylene group is still more preferable.

The above-described linear or branched hydrocarbon chain (preferably, alkyl group) has 4 or more carbon atoms, preferably has 6 or more carbon atoms, more preferably has 8 or more carbon atoms, still more preferably 10 or more carbon atoms, and particularly preferably 12 or more carbon atoms. The upper limit value of the number of carbon atoms is not particularly specified, but the number of carbon atoms can be set, for example, to be less than or equal to 25.

The above-described linear or branched hydrocarbon chain may contain an ether group (—O—), but preferably has no ether group from the viewpoint of improving the releasability.

By using a relatively small addition amount of such a monofunctional polymerizable compound having a hydrocarbon chain, the elasticity of a cured film is reduced and the releasability improves. In addition, in a case where a monofunctional polymerizable compound having a linear or branched alkyl group is used, the interfacial energy between a mold and a cured film is reduced, and therefore, it is possible to further improve the releasability.

Examples of a preferred hydrocarbon group included in the monofunctional polymerizable compound used in the curable composition for imprinting include (1) to (3).

(1) Linear alkyl groups having 8 or more carbon atoms

(2) Branched alkyl groups having 10 or more carbon atoms

(3) Alicyclic or aromatic ring substituted with linear or branched alkyl group having 5 or more carbon atoms

(1) Linear Alkyl Groups Having 8 or More Carbon Atoms

Among the linear alkyl groups having 8 or more carbon atoms, branched alkyl groups having 10 or more carbon atoms are more preferable, branched alkyl groups having 11 or more carbon atoms are still more preferable, and branched alkyl groups having 12 or more carbon atoms are particularly preferable. In addition, branched alkyl groups having 20 or less carbon atoms are preferable, branched alkyl groups having 18 or less carbon atoms are more preferable, branched alkyl groups having 16 or less carbon atoms are still more preferable, and branched alkyl groups having 14 or less carbon atoms are particularly preferable.

(2) Branched Alkyl Groups Having 10 or More Carbon Atoms

Among the above-described branched alkyl groups having 10 or more carbon atoms, branched alkyl groups having 10 to 20 carbon atoms are preferable, branched alkyl groups having 10 to 16 carbon atoms are more preferable, branched alkyl groups having 10 to 14 carbon atoms are still more preferable, and branched alkyl groups having 10 to 12 carbon atoms are particularly preferable.

(3) Alicyclic or Aromatic Ring Substituted with Linear or Branched Alkyl Group Having 5 or More Carbon Atoms

The linear or branched alkyl group having 5 or more carbon atoms is more preferably a linear alkylene group. The number of carbon atoms in the above-described alkyl group is still more preferably 6 or more, still more preferably 7 or more, and still more preferably 8 or more. The number of carbon atoms in the alkyl group is preferably 14 or less, more preferably 12 or less, and still more preferably 10 or less.

The ring structure of an alicyclic or aromatic ring may be a monocyclic ring or a condensed ring, but is preferably a monocyclic ring. In a case where the ring structure thereof is a condensed ring, the number of rings is preferably 2 or 3. The ring structure is preferably a 3- to 8-membered ring, more preferably a 5- to 6-membered ring, and still more preferably a 6-membered ring. In addition, the ring structure is an alicyclic ring or an aromatic ring, but is preferably an aromatic ring. Specific examples of the ring structure include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring, among which a cyclohexane ring, a tricyclodecane ring, an adamantane ring, and a benzene ring are more preferable and a benzene ring is still more preferable.

The monofunctional polymerizable compound used in the curable composition for imprinting is preferably a compound in which a linear or branched hydrocarbon chain having 4 or more carbon atoms is directly bonded to a polymerizable group or through a linking group, and is more preferably a compound in which any one of the above-described (1) to (3) is directly bonded to a polymerizable group. Examples of the linking group include —O—, —C(═O)—, —CH₂—, or a combination thereof. Linear alkyl (meth)acrylate in which a (1) linear alkyl group having 8 or more carbon atoms is directly bonded to a (meth)acryloyloxy group is particularly preferable as the monofunctional polymerizable compound used in the present invention.

Examples of the monofunctional polymerizable compound used in the curable composition for imprinting include the following first group and second group. However, it goes without saying that the present invention is not limited thereto. In addition, the first group is more preferable than the second group.

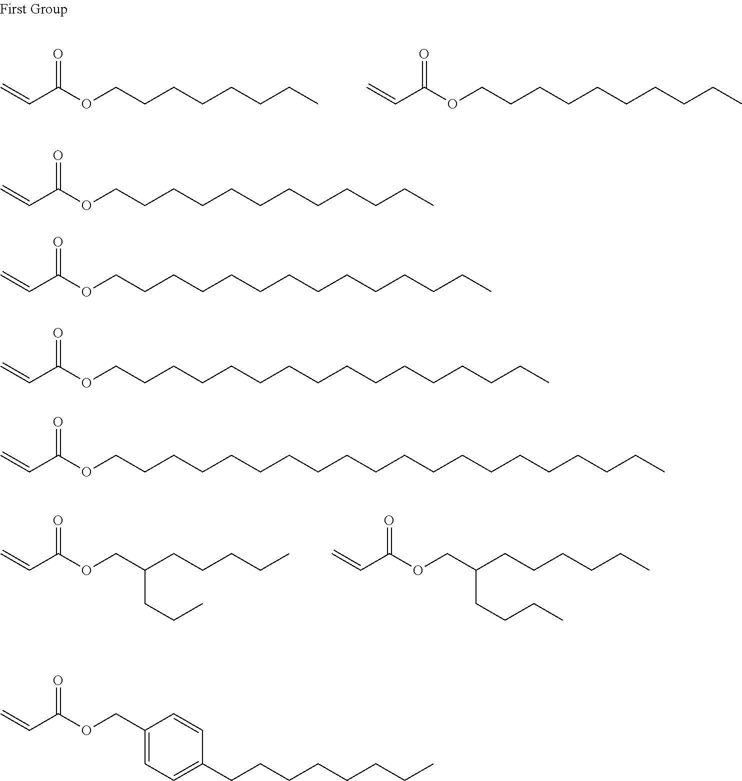

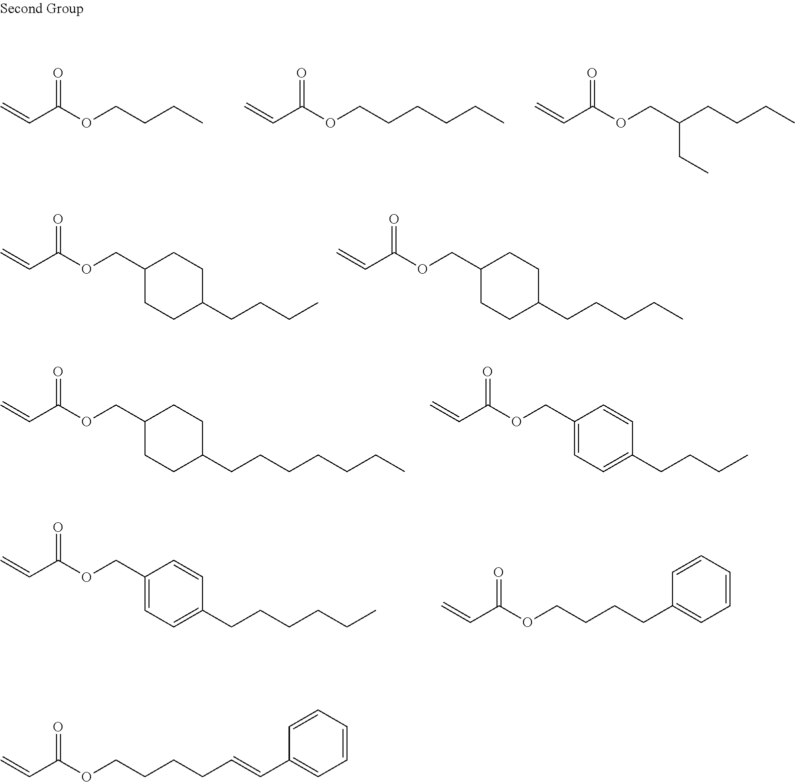

The amount of monofunctional polymerizable compound used in the curable composition for imprinting with respect to the total polymerizable compound in the curable composition for imprinting is greater than 5 mass % and less than 30 mass %. The lower limit value thereof is preferably greater than or equal to 6 mass %, more preferably greater than or equal to 8 mass %, still more preferably greater than or equal to 10 mass %, and particularly preferably greater than or equal to 15 mass %. In addition, the upper limit value thereof is preferably less than or equal to 29 mass %, more preferably less than or equal to 27 mass %, and particularly preferably less than or equal to 25 mass %. In a case where the amount of monofunctional polymerizable compound is set to be greater than or equal to 6 mass % with respect to the total polymerizable compound, it is possible to improve the releasability and to suppress a defect or a damage to a mold at the time of releasing the mold. In addition, by setting the amount thereof to be less than or equal to 29 mass %, it is possible to increase Tg of a cured film of the curable composition for imprinting and to suppress etching workability, particularly waves of a pattern at the time of etching.

In the present invention, a monofunctional polymerizable compound other than the above-described monofunctional polymerizable compound may be used as long as it does not depart from the gist of the present invention. An example thereof includes a monofunctional polymerizable compound among the polymerizable compounds disclosed in JP2014-170949A, and the contents thereof are included in the present specification.

In the present invention, greater than or equal to 90 mass % of the total monofunctional polymerizable compounds contained in the curable composition for imprinting are preferably monofunctional polymerizable compounds having the above-described groups of (1) to (3) and greater than or equal to 95 mass % thereof are more preferably monofunctional polymerizable compounds having the above-described groups of (1) to (3).

The polyfunctional polymerizable compound used in the curable composition for imprinting is not particularly limited, but it preferable that it contains at least one of an alicyclic structure or an aromatic ring structure and has a viscosity at 25° C. of less than or equal to 150 mPa·s. In some cases, such a compound may be referred to as a ring structure-containing polyfunctional polymerizable compound in the description below. By using the ring structure-containing polyfunctional polymerizable compound in the present invention, it is possible to more effectively suppress etching processing characteristics, particularly breakage of a pattern after etching. It is estimated that this is because an etching selection ratio with a processing object (for example, Si, A1, Cr, or an oxide thereof) in a case of etching processing improves.

The curable composition for imprinting may contain only one kind of ring structure-containing polyfunctional polymerizable compound or two or more kinds of ring structure-containing polyfunctional polymerizable compounds.

The molecular weight of the ring structure-containing polyfunctional polymerizable compound used in the curable composition for imprinting is preferably less than or equal to 1,000, more preferably less than or equal to 800, still more preferably less than or equal to 500, still more preferably less than or equal to 350, and still more preferably less than or equal to 250. In a case where the upper limit value of the molecular weight is set to be less than or equal to 1,000, there is a tendency that it is possible to reduce the viscosity.

The lower limit value of the molecular weight is not particularly specified, but the molecular weight can be set, for example, to be greater than or equal to 200.

The number of polymerizable groups contained in the ring structure-containing polyfunctional polymerizable compound used in the curable composition for imprinting is 2 or more, preferably 2 to 7, more preferably 2 to 4, still more preferably 2 or 3, and particularly preferably 2.

The kind of polymerizable group included in the ring structure-containing polyfunctional polymerizable compound used in the curable composition for imprinting is not particularly specified, but is, for example, an ethylenically unsaturated bond-containing group and an epoxy group and preferably an ethylenically unsaturated bond-containing group. Examples of the ethylenically unsaturated bond-containing group include a (meth)acryloyl group and a vinyl group, more preferably a (meth)acryloylf group, and still more preferably an acryloyl group. In addition, the (meth)acryloyl group is preferably a (meth)acryloyloxy group. Two or more kinds of polymerizable groups may be contained in one molecule, or two or more polymerizable groups of the same kind may be contained therein.

The kinds of atoms constituting the ring structure-containing polyfunctional polymerizable compound used in the curable composition for imprinting is not particularly specified, but the monofunctional polymerizable compound thereof is preferably constituted of only atoms selected from carbon atoms, oxygen atoms, hydrogen atoms, and halogen atoms, and is more preferably constituted of only atoms selected from carbon atoms, oxygen atoms, and hydrogen atoms.

The ring structure contained in the ring structure-containing polyfunctional polymerizable compound used in the curable composition for imprinting may be a monocyclic ring or a condensed ring, but it is preferably a monocyclic ring. In a case where the ring structure thereof is a condensed ring, the number of rings is preferably 2 or 3. The ring structure is preferably a 3- to 8-membered ring, more preferably a 5- to 6-membered ring, and still more preferably a 6-membered ring. In addition, the ring structure may be an alicyclic ring or an aromatic ring, but is preferably an aromatic ring. Specific examples of the ring structure include a cyclohexane ring, a norbornane ring, an isobornane ring, a tricyclodecane ring, a tetracyclododecane ring, an adamantane ring, a benzene ring, a naphthalene ring, an anthracene ring, and a fluorene ring, among which a cyclohexane ring, a tricyclodecane ring, an adamantane ring, and a benzene ring are more preferable and a benzene ring is still more preferable.

The number of ring structures in the ring structure-containing polyfunctional polymerizable compound used in the curable composition for imprinting may be 1 or 2 or more, but is preferably 1 or 2 and more preferably 1. In a case of a condensed ring, it is considered that the number of condensed rings is 1.

The ring structure-containing polyfunctional polymerizable compound used in the curable composition for imprinting is preferably represented by (polymerizable group)—(single bond or divalent linking group)—(divalent group having ring structure)—(single bond or a divalent linking group)—(polymerizable group). Here, as the linking group, an alkylene group is more preferable, and an alkylene group having 1 to 3 carbon atoms is more preferable.

The ring structure-containing polyfunctional polymerizable compound used in the curable composition for imprinting is preferably represented by General Formula (1).

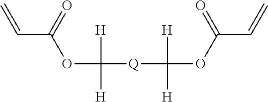

In General Formula (1), Q represents a divalent group having an alicyclic structure or an aromatic ring structure.

The preferred range of an alicyclic ring or an aromatic ring (ring structure) in Q has the same meaning as described above, and the preferred range is also the same.

Examples of the polyfunctional polymerizable compound used in the curable composition for imprinting include the following first group and second group. However, it goes without saying that the present invention is not limited thereto. The first group is more preferable.

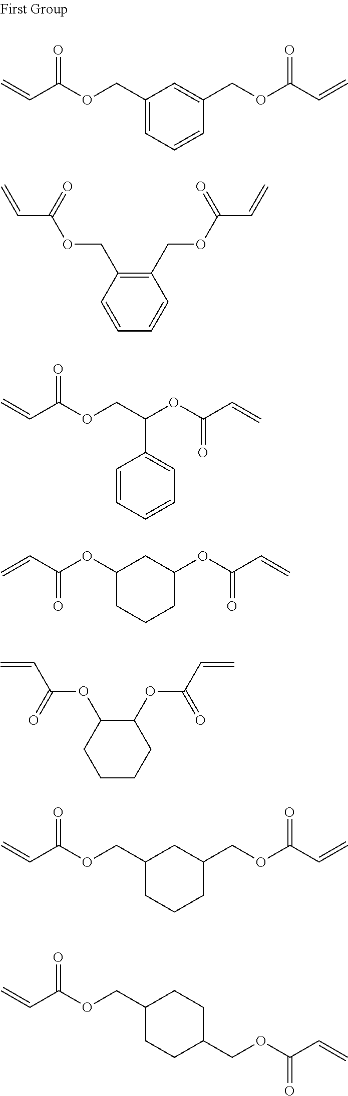

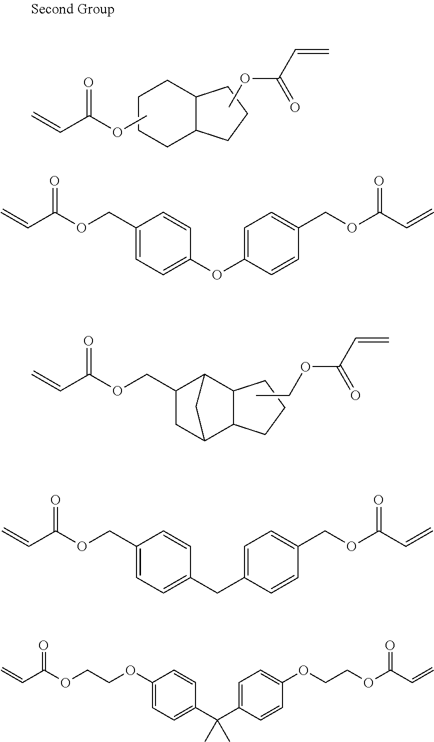

The ring structure-containing polyfunctional polymerizable compound with respect to the total polymerizable compound is preferably contained in the curable composition for imprinting in an amount of greater than or equal to 30 mass %, more preferably greater than or equal to 45 mass %, still more preferably greater than or equal to 50 mass %, and still more preferably greater than or equal to 55. The ring structure-containing polyfunctional polymerizable compound may be contained therein in an amount of greater than or equal to 60 mass % or an amount of greater than or equal to 70 mass %. In addition, the upper limit value is preferably less than 95 mass %, more preferably less than or equal to 90 mass %, and can also be set to be less than or equal to 85 mass %. By setting the lower limit value to be greater than or equal to 30 mass %, the etching selection ratio with a processing object (for example, Si, A1, Cr, or an oxide thereof) in a case of etching processing improves, and therefore, it is possible to suppress breakage of a pattern after etching processing.

The curable composition for imprinting may contain other polyfunctional polymerizable compounds besides the above-described ring structure-containing polyfunctional polymerizable compound. Only one kind or two or more kinds of the other polyfunctional polymerizable compounds may be contained therein.

Examples of the other polyfunctional polymerizable compounds used in the curable composition for imprinting include polyfunctional polymerizable compounds having no ring structure among the polymerizable compounds disclosed in JP2014-170949A, and the contents thereof are included in the present specification. More specifically, for example, the following compounds are exemplified.

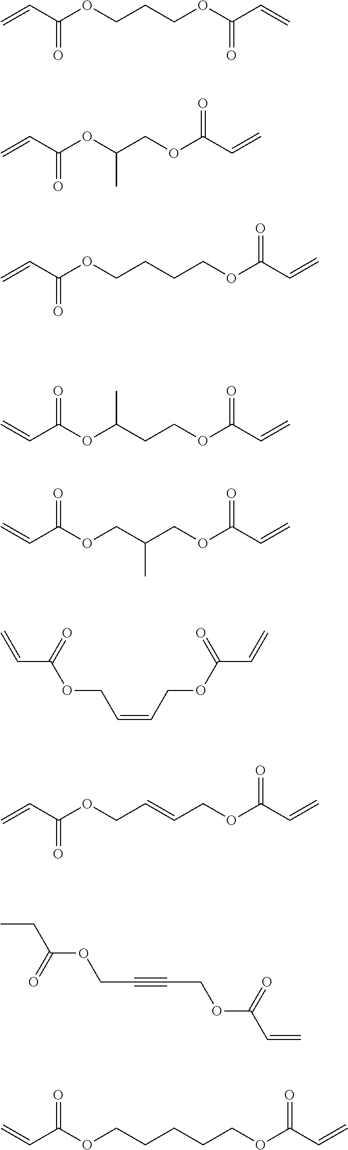

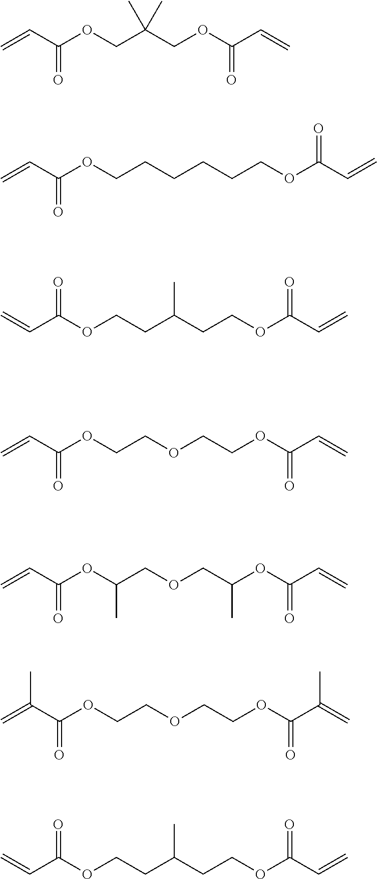

The formulation amount of the other polyfunctional polymerizable compounds in the curable composition for imprinting with respect to the total polymerizable compound in a case of formulating is preferably 5 to 30 mass %. In addition, it is also possible to employ a configuration in which the other polyfunctional polymerizable compounds are not substantially formulated. The expression “not substantially formulated” means that the amount of the other polyfunctional polymerizable compounds in the curable composition for imprinting with respect to the total polymerizable compound is, for example, less than or equal to 3 mass %, and more preferably less than or equal to 1 mass %.

Each component disclosed in JP2013-036027A, JP2014-090133A, JP2013-189537A, and JP2016-037872 can be used as a photopolymerization inhibitor, a sensitizer, a releasing agent, an antioxidant, a polymerization inhibitor, a solvent, and the like which may be formulated with the curable composition for imprinting, in addition to components to be described in examples below. The disclosures of the above-described publications can also be referred to for the formulation amount and the like.

Specific examples of the curable composition for imprinting that can be used in the present invention include compositions to be described in examples below, and compositions disclosed in JP2013-036027A, JP2014-090133A, JP2013-189537A, and JP2016-037872, and the contents thereof are incorporated into the present specification. In addition, the disclosures of the above-described publications can also be referred to for a method for preparing a curable composition for imprinting and forming and a method for forming a film (pattern forming layer), and the contents thereof are incorporated into the present specification.

<Pattern>

A pattern formed through the above-described pattern forming method as described above can be used as a permanent film used in a liquid crystal display device (LCD) or the like or an etching resist for manufacturing a semiconductor element.

In addition, it is possible to form a grid pattern on a glass substrate of a liquid crystal display device using the pattern formed through the above-described pattern forming method to manufacture a polarizing plate having a large screen size (for example, 55 inches or larger than 60 inches) with little reflection and absorption at low cost. For example, polarizing plates disclosed in JP2015-132825A or WO2011/132649A can be manufactured. 1 inch is 25.4 mm.

In addition, the permanent film is bottled in a container such as a gallon bottle or a coat bottle after being manufactured, and is transported and stored therein. In this case, the inside of the container may be substituted with inert nitrogen or argon in order to prevent deterioration. In addition, the temperature in the case of transportation and storage may be normal temperature, but may be controlled within a range of −20° C. to 0° C. in order to prevent deterioration of the permanent film. As a matter of course, it is preferable to block light at a level at which the reaction does not progress.

Specifically, the pattern formed in the present invention can be preferably used for producing a recording medium such as a magnetic disk, a light-receiving element such as a solid image pickup element, a light emitting element such as an LED or organic EL, an optical device such as a liquid crystal display (LCD) device, a diffraction grating, a relief hologram, optical components such as an optical waveguide, an optical filter, and a microlens array, a thin film transistor, an organic transistor, a color filter, an anti-reflection film, a polarizing plate, a polarizing element, an optical film, flat panel display member such as a column material, a nano-biodevice, an immunological analysis chip, a deoxyribonucleic acid (DNA) separation chip, a microreactor, photonic liquid crystal, a guide pattern for forming a fine pattern (directed self-assembly, DSA) using self-assembly of a block copolymer, and the like.

The pattern formed in the present invention is also useful as an etching resist (lithography mask). In a case of using a pattern as an etching resist, a fine pattern is first formed on a substrate, for example, in a nano or micron order through the above-described pattern forming method using a silicon substrate (such as silicon wafer) in which, for example, a thin film of SiO₂ or the like, as a substrate is formed. In the present invention, it is particularly beneficial from the viewpoint that it is possible to form a fine pattern in a nano order, and it is also possible to form a pattern having a size of less than or equal to 50 nm and particularly a size of less than or equal to 30 nm. The lower limit value of the size of the pattern formed through the above-described pattern forming method is not particularly specified, but can be set, for example, to be greater than or equal to 1 nm.

Thereafter, a desired pattern can be formed on a substrate by etching with hydrogen fluoride or the like in a case of wet etching or with etching gas such as CF₄ in a case of dry etching. The pattern has good etching resistance, particularly to dry etching. That is, the pattern formed through the above-described pattern forming method is preferably used as a lithography mask.

### EXAMPLES

Hereinafter, the present invention will be more specifically described with reference to examples. The material, the usage, the proportion, treatment contents, a treatment procedure, and the like shown in Examples below can be appropriately changed without departing from the gist of the present invention. Accordingly, the range in the present invention is not limited to specific examples shown below.

The proportions of each of the components in Tables 1 to 4 are mass ratios.

<Preparation of Compositions for Forming Primer Layer>

Compounds were formulated as described in Tables 1 to 3 and filtered with a 0.1 m PTFE filter to prepare compositions for forming a primer layer shown in Examples 1 to 16 and Comparative Examples 2 to 13.

<Preparation of Curable Compositions for Imprinting>

Mixtures were prepared by mixing compounds as described in Table 4 and further adding 200 mass ppm (0.02 mass %) of 4-hydroxy-2,2,6,6-tetramethylpiperidine-1-oxyl free radical (manufactured by Tokyo Chemical Industry Co., Ltd.) as a polymerization inhibitor with respect to the total amount of the polymerizable compound. These were filtered with a 0.1 μm PTFE filter to prepare curable compositions for imprinting V1 to V4.

<Formation of Adhesive Layer and Primer Layer>

A Silicon wafer was spin-coated with a composition for forming an adhesive layer shown in Example 6 of JP2014-024322A and heated with a hot plate at 220° C. for 1 minute, and a solvent was dried to form an adhesive layer having a thickness of 5 nm. Subsequently, the surface of the adhesive layer was respectively spin-coated with a composition for forming a primer layer shown in Tables 1 to 3 and heated with a hot plate at 100° C. for 1 minute, and a solvent was dried to form a primer layer. The film thickness of the primer layer was measured using an ellipsometer and an atomic force microscope.

<Measurement of Critical Surface Tension>

Each of the critical surface tensions of the adhesive layer and the primer layer formed above was measured.

2 μL of each solvent having different surface tensions was added dropwise to the surface of the adhesive layer or the primer layer, and each contact angle θ at the time of 500 msec was measured. Results of the contact angles (θ) being greater than or equal to 2° were plotted on an xy plane (x: surface tension of solvent, y: cos θ calculated from contact angle θ), linear functions approximating the above-described measurement results were calculated by a least-squares method, and extrapolation values of the above-described linear functions at cos θ being 1 were set as a critical surface tension (unit: mN/m) of the adhesive layer or the primer layer.

Water (surface tension of 72.9 mN/m), glycerin (63.2), formamide (58.5), ethylene glycol (50.2), γ-butyrolactone (44.1), oleic acid (32.2), cyclohexanone (34.1), methyl acetate (25.0) were used as solvents.

The measurement of contact angles was performed at 25° C. using DMs-401 manufactured by Kyowa Interface Science Co., Ltd. Values after 500 msec after droplet impact were measured using n=3, and an average value thereof was set as a contact angle.

The critical surface tension of each primer layer is shown in Tables 1 to 3. The critical surface tension of the adhesive layer was 44 mN/m.

<Measurement of Surface Tension>

Measurement of the surface tension of each composition or compound was performed at 25° C.±0.2° C. using a glass plate using a surface tensiometer SURFACE TENS-IOMETER CBVP-A3 manufactured by Kyowa Interface Science Co., Ltd. The unit is expressed in mN/m.

<Evaluation of Wettability of IJ Liquid Droplet>

Each curable composition for imprinting, which was shown in Table 4 and of which the temperature was adjusted to 25° C. was discharged on the surface of the primer layer obtained above at a small amount of liquid droplet of 6 pL per nozzle using an inkjet printer DMP-2831 manufactured by Fujifilm Dimatix, to coat the surface of the adhesive layer so that liquid droplets are squarely arrayed at an interval of about 880 μm. After the application, ultraviolet (UV) irradiation (irradiation amount: 200 mJ/cm²) was performed in a nitrogen atmosphere within 10 seconds to harden inkjet liquid droplets (IJ liquid droplets).

Thereafter, the liquid droplets were observed with an optical microscope, and the average diameter of the IJ liquid droplets was measured and used as an index of wettability.

A: Average diameter of IJ liquid droplets >800 μm

B: 700 μm<average diameter of IJ liquid droplets 800 μm

C: 600 μm<average diameter of IJ liquid droplets 700 μm

D: 500 μm<average diameter of IJ liquid droplets 600 μm

E: Average diameter of IJ liquid droplets <500 μm

<Evaluation of Surface Roughness of Primer Layer>

A 10 μm angle of the primer layer obtained above was scanned using an atomic force microscope (AFM manufactured by Bruker AXS, Dimension Icon), the arithmetic mean surface roughness (Ra) was measured, and was evaluated based on the following criteria. The results are shown in Tables 1 to 3.

A: Ra<0.4 nm

B: 0.4 nm≤Ra<1.0 nm

C: 1.0 nm≤Ra

<Evaluation of Imprint Pattern Shape>

A curable composition for imprinting, of which the temperature was adjusted to 25° C. was discharged on the surface of the primer layer obtained above at a small amount of liquid droplet of 6 pL per nozzle using an inkjet printer DMP-2831 manufactured by Fujifilm Dimatix, to coat the surface of the above-described primer layer so that liquid droplets are squarely arrayed at an interval of about 100 μm. The curable composition for imprinting was formed in a layer shape. Next, a quartz mold (convex pillar pattern, diameter of 1 μm, groove depth of 500 nm) was brought into press contact with a layer-shaped curable composition for imprinting in a helium atmosphere (substitution rate of greater than or equal to 90 volume %), and the mold was filled with the curable composition for imprinting. A high pressure mercury lamp was used to perform an exposure from the mold side under the condition of 300 mJ/cm² at a point in time 10 seconds have elapsed after imprinting. Then, the mold was peeled off to transfer the pattern to the curable composition for imprinting.

The produced pattern was observed with a scanning electron microscope (SEM).

A: It was confirmed that favorable pattern transfer can be performed on the entire surface of the imprint area.

B: Roughness of the pattern surface was confirmed in a part of the imprint area.

C: Roughness of the pattern surface was confirmed in the entire surface of the imprint area.

<Release Force>

Any one of curable compositions for imprinting V1 to V4, of which the temperature was adjusted to 25° C. was discharged on the surface of the primer layer obtained above at an amount of liquid droplet of 6 pL per nozzle using an inkjet printer DMP-2831 manufactured by Fujifilm Dimatix, to coat the surface of the primer layer so that liquid droplets are squarely arrayed at an interval of about 100 m. The curable composition for imprinting was regarded as a pattern forming layer (layer-shaped curable composition for imprinting). Next, a quartz mold (line pattern having a line width of 20 nm and a depth of 50 nm) was brought into press contact with the pattern forming layer in a He atmosphere (substitution rate of greater than or equal to 90%), and the mold was filled with the curable composition for imprinting. A high pressure mercury lamp was used to perform an exposure from the mold side under the condition of 300 mJ/cm² at a point in time 10 seconds have elapsed after imprinting. Then, the mold was peeled off to transfer the pattern to the pattern forming layer. The release force required for peeling was measured using a load cell.

A: A release force was less than 20 N.

B: A release force was greater than or equal to 20 N.

TABLE 1

| | | | Exam- | Exam- | Exam- | Exam- | Exam- | Exam- | Exam- | Exam- | Exam- |
|---|---|---|---|---|---|---|---|---|---|---|---|
| | | Surface tension | ple 1 | ple 2 | ple 3 | ple 4 | ple 5 | ple 6 | ple 7 | ple 8 | ple 9 |
| A-1 | Polyethylene glycol (Mw = 500) | 44.9 | 0.1 | | | | | | | 0.06 | |
| A-2 | Polyethylene glycol monomethyl ether | 41 | | 0.3 | | | | | | | |
| | (Mw = 500) | | | | | | | | | | |
| A-3 | Polyethylene glycol dimethyl ether | 45.6 | | | 0.5 | | | | | | |
| | (Mw = 500) | | | | | | | | | | |
| A-4 | Polyethylene glycol (Mw = 600) | 45.1 | | | | 0.3 | | | | | 0.15 |
| A-5 | Polyethylene glycol (Mw = 750) | 44.9 | | | | | 0.1 | | | | |
| A-6 | Polyethylene glycol (Mw = 200) | 45.4 | | | | | | 0.3 | | | |
| A-7 | Glycerol | 63.2 | | | | | | | 0.3 | | |
| A-8 | Polyethylene glycol (Mw = 130) | 28.2 | | | | | | | | | |
| A-9 | Polyethylene glycol (Mw = 1,000) | Immeasurable | | | | | | | | | |
| | | (solid) | | | | | | | | | |
| A-10 | Polyethylene glycol (Mw = 2,000) | Immeasurable | | | | | | | | | |
| | | (solid) | | | | | | | | | |
| A-11 | Polyethylene glycol diacrylate | 40.9 | | | | | | | | | |
| A-12 | Ethoxylated bisphenol A diacrylate | Immeasurable | | | | | | | | | |
| | (m + n = 4) | | | | | | | | | | |
| A-19 | Tetraethylene glycol monobenzyl ether | 43.1 | | | | | | | | | |
| | (Mw = 284) | | | | | | | | | | |
| B-1 | 1,3-Phenylenebis(methylene) diacrylate | 39.1 | | | | | | | | 0.24 | |
| B-2 | Trimethylolpropane triacrylate | 38.7 | | | | | | | | | 0.15 |
| C-1 | Propylene glycol monomethyl ether | — | 99.9 | 99.7 | 99.5 | 89.7 | 99.9 | 99.7 | 99.7 | 99.7 | 99.7 |
| | acetate | | | | | | | | | | |
| C-2 | γ-Butyrolactone | — | | | | | | | | | |
| C-3 | Cyclohexanone | — | | | | 10 | | | | | |
| V | Curable composition for imprinting | | V1 | V3 | V4 | V1 | V3 | V1 | V3 | V3 | V4 |
| | Film thickness (nm) | | 3 | 6 | 10 | 5 | 2 | 7 | 10 | 10 | 10 |
| | Critical surface tension (mN/m) | | 53 | 54 | 51 | 53 | 54 | 48 | 56 | 53 | 51 |
| | Wettability of IJ liquid droplets | | A | A | A | A | A | A | A | A | A |
| | Surface roughness | | A | A | A | A | A | A | A | A | A |
| | Imprint pattern shape | | A | A | A | A | A | A | A | A | A |
| | Release force | | A | A | A | A | A | A | A | A | A |

TABLE 2

| | | | Exam- | Exam- | Exam- | Exam- | Exam- | Exam- | Exam- | Exam- | Exam- |
|---|---|---|---|---|---|---|---|---|---|---|---|
| | | Surface tension | ple 10 | ple 11 | ple 12 | ple 13 | ple 14 | ple 15 | ple 16 | ple 17 | ple 18 |
| A-1 | Polyethylene glycol (Mw = 500) | 44.9 | | | | | | | | | |
| A-2 | Polyethylene glycol monomethyl ether | 41 | | | 0.045 | | | | | | |
| | (Mw = 500) | | | | | | | | | | |
| A-3 | Polyethylene glycol dimethyl ether | 45.6 | | | | | 0.6 | | | | |
| | (Mw = 500) | | | | | | | | | | |
| A-4 | Polyethylene glycol (Mw = 600) | 45.1 | | | | | | | | | |
| A-5 | Polyethylene glycol (Mw = 750) | 44.9 | | | | 0.03 | | | | | |
| A-6 | Polyethylene glycol (Mw = 200) | 45.4 | | | | | | | | | |
| A-7 | Glycerol | 63.2 | | | | | | | | | |
| A-8 | Polyethylene glycol (Mw = 130) | 28.2 | | | | | | | | | |
| A-9 | Polyethylene glycol (Mw = 1,000) | Immeasurable | 0.3 | | | | | | | | |
| | | (solid) | | | | | | | | | |
| A-10 | Polyethylene glycol (Mw = 2,000) | Immeasurable | | 0.3 | | | | | | | |
| | | (solid) | | | | | | | | | |
| A-11 | Polyethylene glycol diacrylate | 40.9 | | | | | | 0.1 | | | |
| A-12 | Ethoxylated bisphenol A diacrylate | Immeasurable | | | | | | | 0.2 | | |
| | (m + n = 4) | | | | | | | | | | |
| A-19 | Tetraethylene glycol monobenzyl ether | 43.1 | | | | | | | | 0.3 | 0.3 |
| | (Mw = 284) | | | | | | | | | | |
| B-1 | 1,3-Phenylenebis(methylene) diacrylate | 39.1 | | | 0.255 | | | | | | |
| B-2 | Trimethylolpropane triacrylate | 38.7 | | | | 0.27 | | | | | |
| C-1 | Propylene glycol monomethyl ether | — | 89.7 | 89.7 | 99.7 | 99.7 | 89.4 | 99.9 | 99.8 | 99.7 | 99.7 |
| | acetate | | | | | | | | | | |
| C-2 | γ-Butyrolactone | — | 10 | 10 | | | | | | | |
| C-3 | Cyclohexanone | — | | | | | 10 | | | | |
| V | Curable composition for imprinting | | V2 | V1 | V3 | V1 | V1 | V2 | V1 | V1 | V3 |
| | Film thickness (nm) | | 6 | 6 | 5 | 6 | 13 | 3 | 5 | 8 | 8 |
| | Critical surface tension (mN/m) | | 52 | 49 | 49 | 46 | 55 | 54 | 52 | 54 | 54 |
| | Wettability of IJ liquid droplets | | A | B | B | C | A | A | A | A | A |
| | Surface roughness | | B | C | A | A | A | A | A | A | A |
| | Imprint pattern shape | | B | B | A | A | B | A | A | A | A |
| | Release force | | A | A | A | A | A | B | B | A | A |

| | | | Com- | Com- | Com- | Com- | Com- | Com- | Com- | Com- | Com- | Com- | Com- | Com- | Com- |
|---|---|---|---|---|---|---|---|---|---|---|---|---|---|---|---|
| | | | parative | parative | parative | parative | parative | parative | parative | parative | parative | parative | parative | parative | parative |
| | | | Example 1 | Example 2 | Example 3 | Example 4 | Example 5 | Example 6 | Example 7 | Example 8 | Example 9 | Example 10 | Example 11 | Example 12 | Example 13 |
| A-13 | Polypropylene glycol | 32.7 | None | 0.1 | 0.3 | | | | | | | | | | |
| | (Mw = 700) | | | | | | | | | | | | | | |
| A-14 | Polypropylene glycol dimethyl ether | 31.3 | | | | 0.5 | | | 0.15 | | | | | | |
| | (Mw = 500) | | | | | | | | | | | | | | |
| A-15 | Polypropylene glycol momomethyl | 30.1 | | | | | 0.7 | | | | | | | | |
| | ether (Mw = 700) | | | | | | | | | | | | | | |
| A-16 | Polypropylene glycol triol type | 31.9 | | | | | | 0.06 | | | | | | | |
| | (Mw = 300/m + n + 1 = 4) | | | | | | | | | | | | | | |
| A-17 | Fluorine-based surfactant | 23 | | | | | | | | 0.3 | | 0.06 | | | |
| | (Capstone FS-3100) | | | | | | | | | | | | | | |
| A-18 | Acetylene-based surfactant (OLFINE | 36 | | | | | | | | | 0.1 | | | | |
| | E1010 manufactured by Nissin | | | | | | | | | | | | | | |
| | Chemical Co., Ltd.) | | | | | | | | | | | | | | |
| B-1 | 1,3-phenylenebis(methylene) | 39.1 | | | | | | 0.24 | | | | | 0.3 | | |
| | diacrylate | | | | | | | | | | | | | | |
| B-2 | Trimethylolpropane triacrylate | 38.7 | | | | | | | | | | 0.24 | | 0.3 | |
| B-3 | Hexanediol diacrylate | 34.8 | | | | | | | 0.15 | | | | | | 0.3 |
| C-1 | Propylene glycol monomethyl ether | — | | 99.9 | 89.7 | 99.5 | 99.3 | 99.7 | 99.7 | 99.7 | 89.9 | 99.7 | 99.7 | 89.7 | 99.7 |
| | acetate | | | | | | | | | | | | | | |
| C-2 | γ-Butyrolactone | — | | | | | | | | | 10 | | | | |
| C-3 | Cyclohexanone | — | | | 10 | | | | | | | | | 10 | |
| V | Curable composition for imprinting | | V3 | V1 | V2 | V4 | V1 | V1 | V3 | V2 | V2 | V3 | V4 | V1 | V2 |
| | Film thickness (nm) | | — | 3 | 6 | 10 | 14 | 5 | 5 | 4 | 2 | 6 | 6 | 5 | 5 |
| | Critical surface tension (mN/m) | | 44 | 42 | 41 | 43 | 41 | 42 | 42 | 28 | 36 | 29 | 44 | 44 | 44 |
| | Wettability of IJ liquid droplets | | D | E | E | E | E | E | E | E | D | E | D | D | D |
| | Surface roughness | | B | B | B | B | C | B | B | B | B | B | A | A | A |
| | Imprint pattern shape | | A | A | A | B | C | A | A | B | A | A | A | A | A |
| | Release force | | A | A | A | A | A | A | A | A | A | A | A | A | A |

A-1: Polyethylene glycol (Mw = 500) 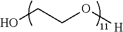
A-2: Polyethylene glycol monomethyl ether (Mw = 500) 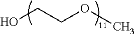
A-3: Polyethylene glycol dimethyl ether (Mw = 500) 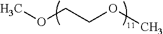
A-4: Polyethylene glycol (Mw = 600) 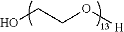
A-5: Polyethylene glycol (Mw = 750) 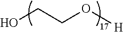
A-6: Polyethylene glycol (Mw = 200) 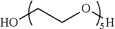
A-7: Glycerol 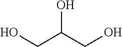
A-9: Polyethylene glycol (Mw = 1,000) 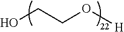
A-10: Polyethylene glycol (Mw = 2,000) 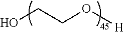
A-11: Polyethylene glycol diacrylate 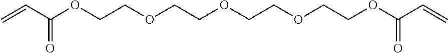 [SMILES: C=CC(=O)OCCOCCOCCOCCOC(=O)C=C]
A-12: Ethoxylated bisphenol A diacrylate (m + n = 4) 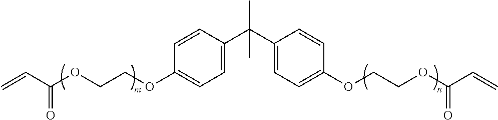
A-13: Polypropylene glycol (Mw = 700) 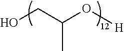
A-14: Polypropylene glycol dimethyl ether (Mw = 500) 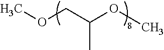
A-15: Polypropylene glycol monomethyl ether (Mw = 700) 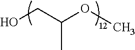
A-16: Polypropylene glycol triol type (Mw = 300/m + n + l = 4) 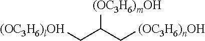
A-17: Fluorine-based surfactant (Capstone FS-3100)
Surfactant containing fluorocarbon and polyethylene glycol structures
A-18: Acrylene-based surfactant (OLFINE E1010 manufactured by Nissin Chemical Co., Ltd.)
Surfactant contaning acetylene structure and polyethylene glycol structure
A-19: Tetraethylene glycol monobenzyl ether (Mw = 284) 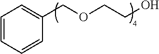
B-1: 1,3-phenylenebis(methylene) diacrylate 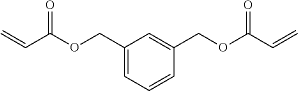 [SMILES: C=CC(=O)OCc1cccc(COC(=O)C=C)c1]
B-2: Trimethylolpropane triacrylate 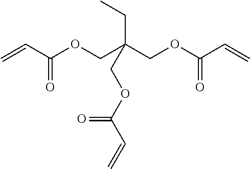 [SMILES: C=CC(=O)OCC(CC)(COC(=O)C=C)COC(=O)C=C]
B-3: Hexanediol diacrylate

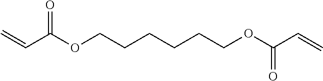 [SMILES: C=CC(=O)OCCCCCCOC(=O)C=C]

TABLE 4

| | V1 | V2 | V3 | V4 |
|---|---|---|---|---|
| 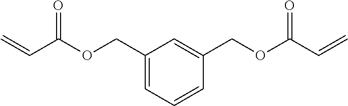 [SMILES: C=CC(=O)OCc1cccc(COC(=O)C=C)c1] | 60 | 70 | 60 | 60 |
| 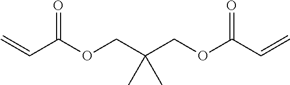 | 20 | | | |
| 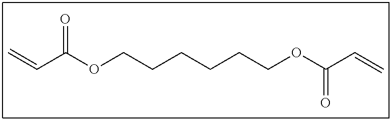 [SMILES: C=CC(=O)OCCCCCCOC(=O)C=C] | | 15 | | |
| 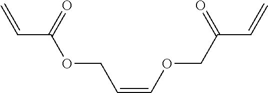 | | | 25 | 25 |
| 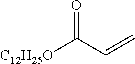 | 20 | 15 | 15 | 15 |
| 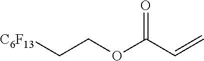 | 2 | 1 | | |
| 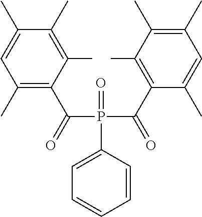 [SMILES: Cc1cc(C)c(C(=O)P(=O)(C(=O)c2c(C)cc(C)c(C)c2C)c2ccccc2)c(C)c1C] | 2 | 2 | 2 | 2 |
| 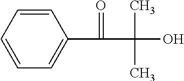 | | 2 | 2 | 2 |
| 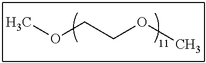 | 3 | 3 | | |
| 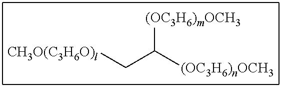 | | | 3 | |

In Table 4 above, n+m+1 is 7 to 13.

As is apparent from the above-described results, the composition for forming a primer layer of the present invention had excellent wettability. Furthermore, a composition for forming a primer layer having small surface roughness, excellent pattern formability of an obtained imprint pattern, and a small release force was obtained.

### EXPLANATION OF REFERENCES

11: substrate
12: adhesive layer
13: primer layer
14: curable composition for imprinting
15: pattern
21: adhesive layer
22: curable composition for imprinting

What is claimed is:

1. A composition for forming a primer layer for imprinting which satisfies at least one of A and B,
A: a component having a surface tension of greater than or equal to 40 mN/m at 25° C. is contained, and
B: a critical surface tension of a primer layer formed of the composition for forming a primer layer for imprinting is greater than or equal to 46 mN/m at 25° C.

2. The composition for forming a primer layer for imprinting according to claim 1,
wherein the component having a surface tension of greater than or equal to 40 mN/m at 25° C. is contained in a component constituting the primer layer in a proportion of greater than or equal to 20 mass %.

3. The composition for forming a primer layer for imprinting according to claim 1 which contains a compound having a polyalkylene glycol structure including a linear alkylene group and an oxygen atom.

4. The composition for forming a primer layer for imprinting according to claim 3,
wherein the compound having the polyalkylene glycol structure including the linear alkylene group and the oxygen atom is the component having a surface tension of greater than or equal to 40 mN/m at 25° C.

5. The composition for forming a primer layer for imprinting according to claim 1 which contains a compound having a polyethylene glycol structure.

6. The composition for forming a primer layer for imprinting according to claim 5,
wherein the compound having a polyethylene glycol structure is the component having a surface tension of greater than or equal to 40 mN/m at 25° C.

7. The composition for forming a primer layer for imprinting according to claim 1,
wherein at least one kind of the component having a surface tension of greater than or equal to 40 mN/m at 25° C. does not have a polymerizable group.

8. The composition for forming a primer layer for imprinting according to claim 1,
wherein at least one kind of the component having a surface tension of greater than or equal to 40 mN/m at 25° C. is a liquid at 25° C.

9. The composition for forming a primer layer for imprinting according to claim 1,
wherein greater than or equal to 95 mass % of the component which constitutes the primer layer and is contained in the composition for forming a primer layer for imprinting is a liquid at 25° C.

10. The composition for forming a primer layer for imprinting according to claim 1,
wherein a weight-average molecular weight of the component having a surface tension of greater than or equal to 40 mN/m at 25° C. is greater than or equal to 200 and less than 1,000.

11. A primer layer for imprinting,
wherein a critical surface tension at 25° C. is greater than or equal to 46 mN/m.

12. The primer layer for imprinting according to claim 11 which is formed of the composition for forming a primer layer for imprinting;
wherein the composition satisfies at least one of A and B,
A: a component having a surface tension of greater than or equal to 40 mN/m at 25° C. is contained, and
B: a critical surface tension of a primer layer formed of the composition for forming a primer layer for imprinting is greater than or equal to 46 mN/m at 25° C.

13. The primer layer for imprinting according to claim 11,
wherein a thickness is less than or equal to 10 nm.

14. A laminate comprising:
the primer layer for imprinting according to claim 11; and
a layer which is formed of a curable composition for imprinting and positioned on a surface of the primer layer for imprinting.

15. The laminate according to claim 14, further comprising:
an adhesive layer on a surface of the primer layer for imprinting on an opposite side to the side where the layer formed of the curable composition for imprinting is positioned.
